(19) United States
(12) Patent Application Publication
(10) Pub. No.: US 2018/0287377 A1
(43) Pub. Date: Oct. 4, 2018

(54) Electrostatic Discharge Protection Device and Circuit Apparatus

(71) Applicant: TDK Corporation, Tokyo (JP)

(72) Inventors: Lei Zou, Kobenhavn (DK); Gino Rocca, Copenhagen (DK)

(21) Appl. No.: 15/764,872

(22) PCT Filed: Sep. 29, 2015
(86) PCT No.: PCT/EP2015/072449

§ 371 Date: Mar. 29, 2018

(51) Int. Cl. H02H 9/04; H01L 27/02; H02H 1/00

(52) U.S. Cl. CPC H02H 9/046; H02H 1/0007; H01L 27/0285

(57) ABSTRACT

An electrostatic discharge protection device and a circuit apparatus are disclosed. In an embodiment, the electrostatic discharge (ESD) includes a detection circuit configured to distinguish between a positive ESD event and a high-voltage rising pad pulse on the high voltage supply terminal, a control circuit is configured to provide a control signal on its output dependent on a detection output signal of the detection circuit and a transistor, wherein the transistor is coupled to a reference potential terminal and a high voltage supply terminal and a control input of the transistor is coupled to the output of the control circuit.

This patent application is a national phase filing under section 371 of PCT/EP2015/072449, filed Sep. 29, 2015, which is incorporated herein by reference in its entirety.

### TECHNICAL FIELD

The invention relates to an electrostatic discharge (ESD) protection device. Furthermore, the invention relates to a circuit apparatus comprising the ESD protection device and a programmable device.

### BACKGROUND

In order to prevent an integrated circuit (IC) or an application specific integrated circuit (ASIC) from overvoltage ESD damage, ESD overvoltage protection circuits are usually used. For ESD overvoltage protection mainly a diode-clamping ESD protection circuit, for instance with one diode from pad to rail power supply and one diode from ground to pad, is used which limits any voltage higher than the rail power supply or below ground.

New applications require integration of one-time programming (OTP) circuits into ASICs. A programming voltage of the one-time programming circuit can be in the range of 6-8V volt level. For instance, in a microelectromechanical systems (MEMS) microphone ASICs, during a calibration operation, a high-voltage pad is used for one-time programming, which also has to be ESD-protected.

Patent Application Publication No. US 2009/0135532 A1 discloses an electrostatic discharge (ESD) protection circuit. A transistor is coupled between a node and a ground, and has a gate coupled to the ground. A diode chain is coupled between the node and a pad, and comprises a plurality of first diodes connected in series, wherein the first diode is coupled in a forward conduction direction from the pad to the node. A second diode is coupled between the node and the pad, and the second diode is coupled in a forward conduction direction from the node to the pad.

### SUMMARY OF THE INVENTION

Embodiments of the present invention provide an electrostatic discharge (ESD) protection device and a circuit apparatus comprising the ESD protection device allowing for a reliable ESD protection, in particular allowing for a reliable ESD protection under a normal and a programming operation mode.

According to a first aspect, embodiments of the invention are distinguished by an electrostatic discharge (ESD) protection device coupleable to at least one high voltage supply terminal of a circuit to be protected, in particular to at least one high voltage supply terminal of a programmable device. The ESD protection device comprises a detection circuit, a control circuit and a transistor. The detection circuit is arranged and configured to distinguish between a positive ESD event and a high-voltage rising pad pulse on the high voltage supply terminal. The control circuit is configured to provide a control signal on its output dependent on a detection output signal of the detection circuit, and the transistor is coupled to a reference potential terminal and a high voltage supply terminal, and a control input of the transistor is coupled to the output of the control circuit.

In various embodiments the ESD protection device is cost-effective in terms of chip area and can be fully integrated in a submicron CMOS IC or ASIC. There is no need for a diode, in particular an integrated diode. An ESD protection with robust ESD performance for high voltage applications and with no gate oxide reliability concerns can be reached.

In various other embodiments the transistor is arranged and configured such that in an on-state of the transistor it provides a low impedance path from the high voltage supply terminal to the reference potential terminal, in particular to a ground potential for diverting an ESD discharge current away from the circuit to be protected, i.e., the programmable device. An operation region of the transistor is well defined. The transistor can comprise only one low-voltage transistor and/or one medium-voltage transistor and/or one high-voltage transistor.

The ESD protection device is able to steer both positive and negative ESD pulses away from the circuit being protected. No additional transistors or diodes may be necessary.

According to an embodiment of the first aspect, the ESD protection device comprises a capacitor circuit for AC-coupling or high pass coupling the high voltage supply terminal to an input of the detection circuit.

According to a further embodiment of the first aspect, the detection circuit comprises a threshold detection circuit configured to detect an ESD event when an input signal of the detection circuit exceeds a given threshold. This allows for an easy implementation of the detection circuit and a cost-effective production of the ESD protection device.

According to a further embodiment of the first aspect, the threshold of the detection circuit is configurable. This allows for a flexible adjustment to the requirements of the high voltage application.

According to a further embodiment of the first aspect, the threshold of the detection circuit comprises a comparator. This allows for an easy implementation of the detection circuit and a cost-effective production of the ESD protection device.

According to a further embodiment of the first aspect, the comparator comprises a voltage divider and a first inverter, wherein the voltage divider is connected in series with the capacitor circuit and an input of the first inverter is coupled to the voltage divider for tapping a partial voltage of the voltage divider.

According to a further embodiment of the first aspect, the detection circuit comprises only transistors as active components. This allows for an easy implementation of the detection circuit and a cost-effective production of the ESD protection device. In particular no diodes are used.

According to a further embodiment of the first aspect, the control circuit comprises a second inverter. Thus, the control circuit allows for transforming the output signal of the detection circuit in an appropriate control signal for the transistor.

According to a further embodiment of the first aspect, the transistor comprises two low voltage n-channel metal-oxide-semiconductor field-effect transistors NMOS_1, NMOS_2 arranged in series. This allows for applying a higher voltage on the high voltage supply terminal.

According to a further embodiment of the first aspect, the transistor comprises two low voltage n-channel metal-oxide-semiconductor field-effect transistors arranged in series, wherein the respective NMOS transistors are each arranged in a deep N-well. This allows for applying a higher voltage on the high voltage supply terminal and a reduced early reverse breakdown risk of a parasitic diode formed by a drain of the LV NMOS-transistor connected to the high voltage supply terminal and a common substrate.

According to a further embodiment of the first aspect, the transistor comprises a high voltage n-channel metal-oxide-semiconductor field-effect transistor comprising a high voltage N-well and a P-well.

According to a second aspect, the invention is distinguished by a circuit apparatus comprising an ESD protection device according to the first aspect and a programmable device, wherein the ESD protection device is coupled to a high voltage supply terminal of the programmable device. The ESD protection device may comprise any structural and functional features as described above.

### BRIEF DESCRIPTION OF THE DRAWINGS

Further features, refinements and expediencies become apparent from the following description of the exemplary embodiments in connection with the figures. These are as follows:

FIG. 1 is a block diagram of a circuit apparatus comprising an electrostatic discharge (ESD) protection device;

FIG. 2 is an exemplary schematic diagram of the ESD protection device;

FIG. 3 is a device cross-sectional view of a first embodiment of a transistor;

FIG. 4 is a device cross-sectional view of a second embodiment of the transistor; and

FIG. 5 is a device cross-sectional view of a third embodiment of the transistor.

Like elements, elements of the same kind and identically acting elements may be provided with the same reference numerals in the figures.

### DETAILED DESCRIPTION OF ILLUSTRATIVE EMBODIMENTS

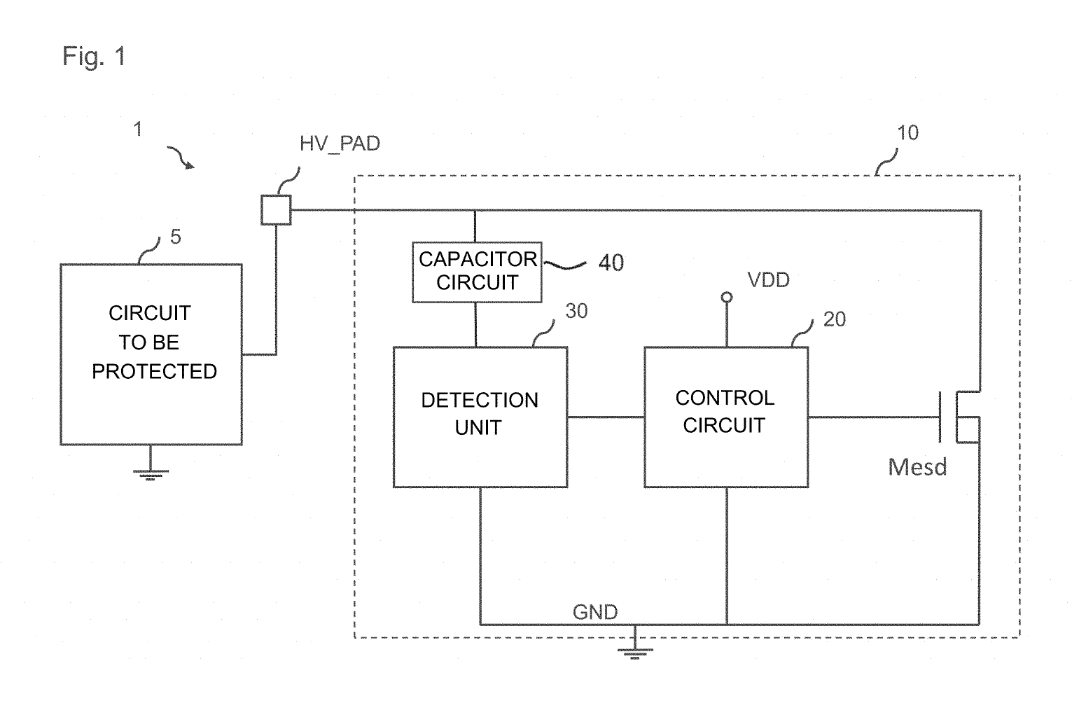

FIG. 1 shows a block diagram of a circuit apparatus 1 comprising an electrostatic discharge (ESD) protection device 10 and a circuit 5 to be protected. The circuit 5 to be protected may comprise a programmable device, for instance a one-time programmable memory.

The ESD protection device 10 is coupled to a high voltage supply terminal HV_PAD of the circuit 5 to be protected. The ESD protection device 10 and the circuit 5 to be protected may be integrated on the same die. The circuit apparatus 1 may be an application specific integrated circuit (ASIC), for example, for a microelectromechanical systems application and/or a microphone application.

The ESD protection device 10 comprises a transistor Mesd coupled to a reference potential terminal GND and the high voltage supply terminal HV_PAD. Preferably the reference potential is a ground potential.

Furthermore the ESD protection device 10 comprises a control circuit 20 for the transistor Mesd. An output of the control circuit 20 is coupled to a control input of the transistor Mesd.

The ESD protection device 10 comprises a detection circuit 30 configured to distinguish between a positive ESD event and a high-voltage rising pad pulse on the high voltage supply terminal HV_PAD. An output of the detection circuit 30 is coupled to an input of the control circuit 20.

The detection circuit 30 may comprise a threshold detection circuit 30 with a configurable voltage threshold. The threshold detection circuit 30 may be configured to detect a voltage signal at the high voltage supply terminal HV_PAD once it exceeds the selected voltage threshold and to provide a corresponding trigger signal on its output.

Preferably the voltage threshold is set higher than a required high-voltage pad pulse, for example, higher than a required high-voltage pad pulse for the programming of the programmable device.

During an ESD event the control circuit 20 activates the transistor Mesd by providing an appropriate control signal at the control input of the transistor Mesd, in particular at a gate of the transistor Mesd, such that the transistor Mesd turns on thus providing a low impedance path between the high voltage supply terminal HV_Pad and the reference potential terminal GND and diverting an ESD discharge current away from the circuit 5 to be protected.

The ESD protection device 10 may comprise a capacitor circuit 40 for AC coupling or high pass coupling an input of the detection circuit 30 with the high voltage supply terminal HV_PAD.

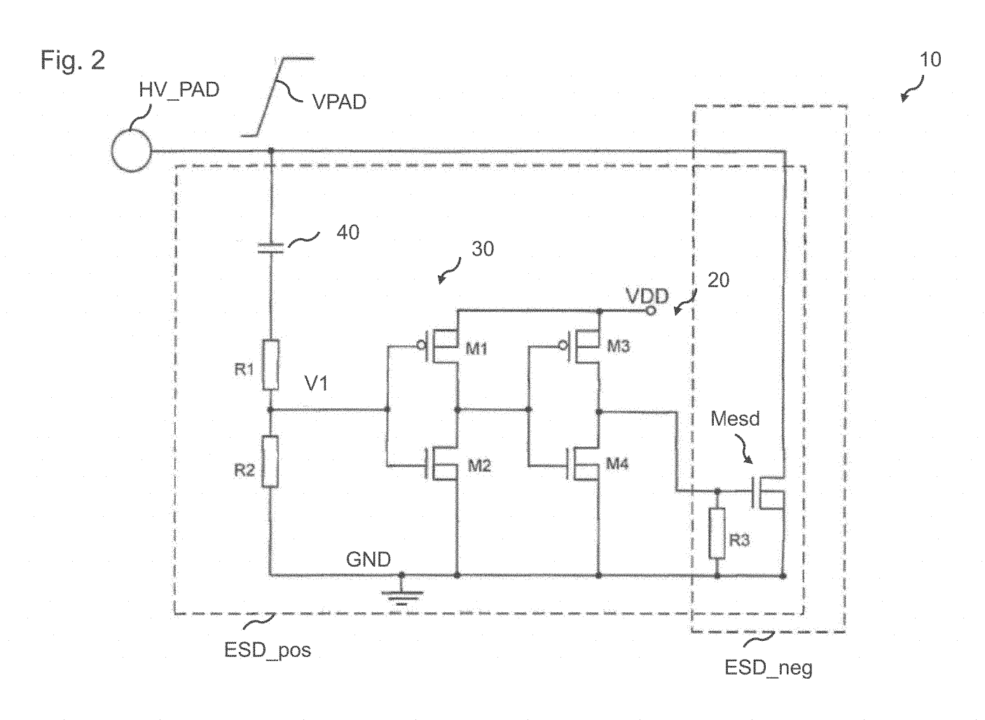

FIG. 2 shows an exemplary schematic diagram of the ESD protection device 10.

The detection circuit 30 comprises, for instance, a voltage divider, for example, a resistor chain with a first resistor R1 and a second resistor R2, and a first inverter. The voltage divider is connected in series with the capacitor circuit 40 across the reference potential terminal GND and the high voltage supply terminal HV_PAD. An input of the first inverter is coupled to the voltage divider such that, by a voltage division, an input voltage of the first inverter is given according equation (1) as

V1=VPAD[R2/(R1+R2)] eq. (1)

wherein VPAD is the voltage level at the high voltage supply terminal HV_PAD.

The first inverter may comprise a first transistor and a second transistor. The first transistor may be an NMOS transistor and the second transistor may be a PMOS transistor. The gates of the first transistor and second transistor may be at the same bias, which means that they are always in a complementary state.

The control circuit 20 is configured to transform the output signal of the detection circuit 30 into an appropriate control signal for the transistor Mesd. The control circuit 20 may comprise a second inverter. The second inverter may comprise also an n-channel metal-oxide-semiconductor field-effect transistor and a p-channel metal-oxide-semiconductor field-effect transistor.

In normal operation the input voltage V1 of the first inverter is lower than a transition voltage of the first inverter, which means that the first inverter outputs a high signal and the second inverter of the control circuit 20 outputs a low signal. The transistor Mesd is in an off-state.

When the input voltage V1 of the inverter exceeds the transition voltage of the first inverter, the first inverter outputs a low signal and the second inverter outputs a high signal. As in this case the gate of the transistor Mesd is pulled high to a supply voltage VDD, such that the transistor Mesd turns on and shunts the high voltage supply terminal HV_PAD to ground.

The voltage threshold of the detection circuit 30 may be given by equation (2)

Vesd=Vtrans*(R1+R2)/R2

wherein Vesd is the voltage threshold and Vtrans is the transition voltage of the first inverter. The voltage threshold of the detection circuit 30 may be configurable by using for instance one or more tunable resistors for the voltage divider.

The transition voltage of the first inverter may be half the supply voltage of the first inverter, and the resistors R1, R2 of the voltage divider may be rated to adjust the voltage threshold. During operation of the circuit apparatus 1 the voltage level at the high voltage supply terminal HV_PAD is compared with the voltage threshold and determines the on/off state of the transistor Mesd.

Assuming a rail power supply of the circuit apparatus 1, in particular the rail power supply of the ASIC, is 3.6 V and the required high voltage rising pad pulse is 6 V. The voltage threshold may be selected to be 7 V where the positive ESD protection starts triggering.

When the voltage level VPAD on the high voltage supply terminal HV_PAD is lower than the voltage threshold of the detection circuit 30, so that the input voltage V1 of the first inverter is below the transition voltage of the first inverter and the transistor Mesd remains in the off-state. When the voltage level VPAD on the high voltage supply terminal HV_PAD is equal to or higher than the voltage threshold of the detection circuit 30, so that the input voltage V1 of the first inverter is above the transition voltage of the first inverter and the transistor Mesd is in the on-state.

As a result, the ESD protection device 10 can distinguish between a positive ESD event and a required high voltage rising pad pulse. Therefore, the ESD protection device 10 does not falsely trigger the transistor Mesd, but only when a positive or negative ESD event occurs.

The ESD protection device 10 is able to steer both positive and negative ESD pulses away from the circuit 5 being protected. The negative ESD protection is triggered when a falling voltage at the high-voltage supply terminal is lower than the reference potential, in particular the ground potential, and a low impedance path is built between the high-voltage supply terminal and the reference potential terminal GND. The ESD protection device 10 comprises a positive ESD protection part ESD_pos and negative ESD protection part ESD_neg. All circuit components of the ESD protection device 10 are used for positive ESD protection and only a resistor R3 of the control circuit 20 and the transistor Mesd are used for negative ESD protection. Thus, the negative ESD protection part ESD_neg reuses components of the positive ESD protection part ESD_pos. No additional transistors or diodes are necessary.

During a negative ESD event, the transistor Mesd is internal ON by means of its drain-source PN junction conduction. The resistor R3 is optional. The Resistor R3 is used to set a ground potential of the gate of transistor Mesd at initial condition so that the transistor Mesd can be off even no control signal is available.

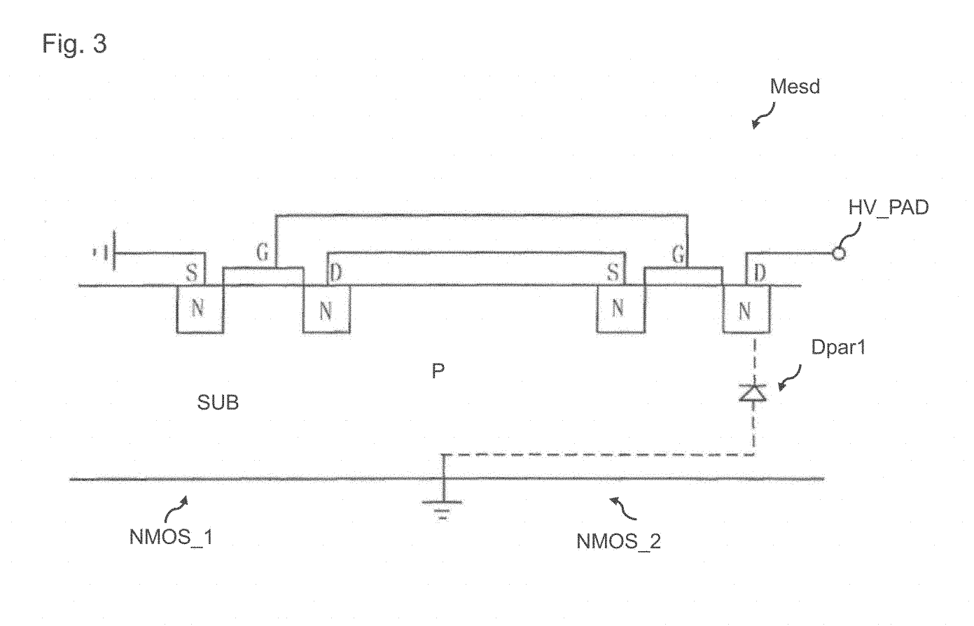

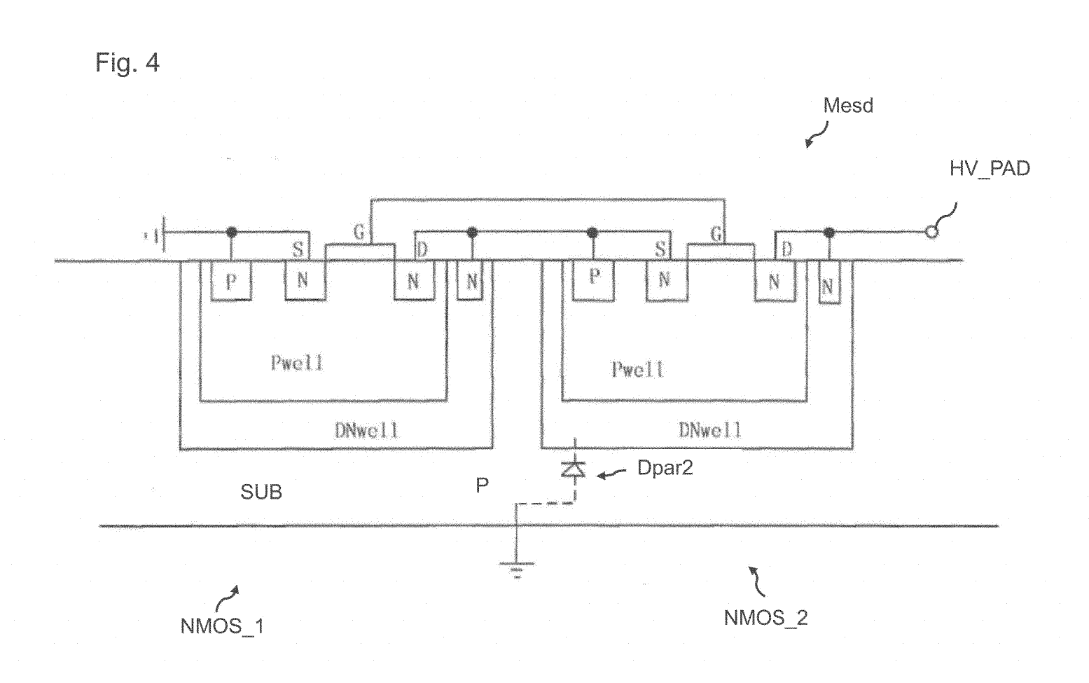

FIG. 3 shows a device cross-sectional view of a first embodiment of the transistor Mesd. The transistor Mesd comprises two low voltage n-channel metal-oxide-semiconductor field-effect transistors (LV NMOS-transistors) NMOS_1, NMOS_2 arranged in series. In FIG. 4 a doping of a source S, drain D and gate G of the LV NMOS-transistors NMOS_1, NMOS_2 is shown. A transistor substrate SUB is p-doped. This allows for a higher voltage on the high voltage supply terminal HV_PAD.

Alternatively, the transistor Mesd may comprise two medium voltage n-channel metal-oxide-semiconductor field-effect transistors (MV NMOS-transistors) arranged in series.

For avoiding an early reverse breakdown risk of a parasitic diode Dpar1 when applying a high voltage on the high voltage supply terminal HV_PAD the transistor Mesd may be further improved.

The parasitic diode Dpar 1 may be formed by a drain D of the LV NMOS-transistor NMOS_2 connected to the high voltage supply terminal HV_PAD and a common substrate SUB of the LV NMOS-transistors NMOS_1, NMOS_2. The early reverse breakdown risk of the parasitic diode results from thin N-channel doping dimensions in a drain area of the LV-NMOS transistors NMOS_1, NMOS_2.

FIG. 4 shows a device cross-sectional view of a second embodiment of the transistor Mesd. The transistor Mesd comprises two low voltage n-channel metal-oxide-semiconductor field-effect transistors NMOS_1, NMOS_2 arranged in series, wherein the respective NMOS transistors are each arranged in a deep N-well. The deep N-wells may be used to isolate the respective NMOS transistors from the substrate SUB of the other NMOS transistors.

Alternatively the transistor Mesd may comprise two medium voltage n-channel metal-oxide-semiconductor field-effect transistors arranged (MV-NMOS) in series, wherein the respective NMOS transistors are each arranged in a deep N-well.

In this case a qualified parasitic diode Dpar2 is formed by the deep N-well of one NMOS-transistor and the substrate SUB. The parasitic diode Dpar2 is a qualified diode due to the significant PN junction dimension of this parasitic diode Dpar2. Therefore, an early reverse breakdown risk of the parasitic diode Dpar2 is reduced.

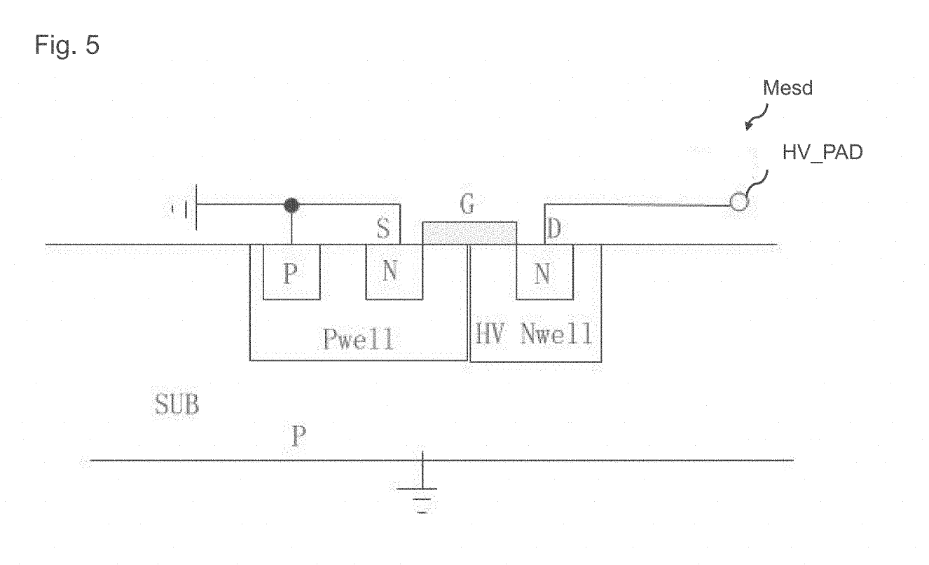

FIG. 5 shows a device cross-sectional view of a third embodiment of the transistor Mesd. The transistor Mesd comprises a high voltage n-channel metal-oxide-semiconductor field-effect transistors (HV NMOS). The NMOS transistor is arranged in the substrate SUB. On top of the substrate SUB, a high voltage N-well and a P-well are arranged. A maximum drain-source voltage of the HV N-MMOS transistor may be 16 V. Accordingly the high voltage pad pulse can be up to 16 V.

1-12. (canceled)

13. An electrostatic discharge (ESD) protection device coupleable to at least one high voltage supply terminal of a circuit to be protected, the ESD comprising:
a detection circuit configured to distinguish between a positive ESD event and a high-voltage rising pad pulse on the high voltage supply terminal;
a control circuit is configured to provide a control signal on its output dependent on a detection output signal of the detection circuit; and
a transistor,
wherein the transistor is coupled to a reference potential terminal and a high voltage supply terminal and a control input of the transistor is coupled to the output of the control circuit.

14. The ESD protection device according to claim 13, further comprising a capacitor circuit for AC-coupling or high pass coupling the high voltage supply terminal to an input of the detection circuit.

15. The ESD protection device according to claim 13, wherein the detection circuit comprises a threshold detection circuit configured to detect an ESD event when an input signal of the detection circuit exceeds a given threshold.

16. The ESD protection device according to claim 15, wherein the threshold of the detection circuit is configurable.

17. The ESD protection device according to claim 15, wherein the threshold detection circuit comprises a comparator.

18. The ESD protection device according to claim 17, wherein the comparator comprises a voltage divider and a first inverter, and wherein the voltage divider is connected in series with a capacitor circuit and an input of the first inverter is coupled to the voltage divider for tapping a partial voltage of the voltage divider.

19. The ESD protection device according to claim 13, wherein the detection circuit comprises only transistors as active components.

20. The ESD protection device according to claim 13, wherein the control circuit comprises a second inverter.

21. The ESD protection device according to any one of claims 13, wherein the transistor comprises two low voltage n-channel metal-oxide-semiconductor field-effect transistors NMOS_1, NMOS_2 arranged in series.

22. The ESD protection device according to claim 13, wherein the transistor comprises two low voltage n-channel metal-oxide-semiconductor field-effect transistors NMOS_1, NMOS_2 arranged in series, and wherein the respective NMOS transistors are each arranged in a deep N-well.

23. The ESD protection device according to claim 13, wherein the transistor comprises a high voltage n-channel metal-oxide-semiconductor field-effect transistor comprising a high voltage N-well and a P-well.

24. A circuit apparatus comprising:
the ESD protection device according to claim 13; and
a programmable device,
wherein the ESD protection device is coupled to a high voltage supply terminal of the programmable device.
